(19) United States
(12) Patent Application Publication
(10) Pub. No.: US 2026/0150690 A1
(43) Pub. Date: May 28, 2026

(54) SEMICONDUCTOR PACKAGE

(71) Applicant: Samsung Electronics Co., Ltd., Suwon-si (KR)

(72) Inventors: Jaejun Lee, Suwon-si (KR); Sunghyun Sim, Suwon-si (KR); Huiyeong Jang, Suwon-si (KR)

(21) Appl. No.: 19/290,614

(22) Filed: Aug. 5, 2025

(30) Foreign Application Priority Data
Nov. 22, 2024 (KR) 10-2024-0168491

(51) Int. Cl. H01L 23/00; H01L 23/31; H01L 23/498

(52) U.S. Cl. CPC H10W 42/121; H10W 74/121; H10W 90/401; H10W 90/701; H10W 74/15; H10W 90/724; H10W 90/734

(57) ABSTRACT

A semiconductor package includes a package substrate; an interposer substrate; a chip structure; first bumps disposed between the interposer substrate and the chip structure; second bumps disposed between the interposer substrate and the package substrate; connection bumps; an underfill region surrounding each of the first bumps; a molding member surrounding the chip structure and the underfill region; and a reinforcing member on the chip structure and the molding member, wherein a coefficient of thermal expansion of a first region including the chip structure and the molding member is lower than a coefficient of thermal expansion of the reinforcing member, and a coefficient of thermal expansion of a second region including the underfill region, the first bumps, and the interposer substrate is higher than the coefficient of thermal expansion of the first region.

### CROSS-REFERENCE TO RELATED APPLICATION(S)

This application claims benefit of priority to Korean Patent Application No. 10-2024-0168491 filed on Nov. 22, 2024 in the Korean Intellectual Property Office, the disclosure of which is incorporated herein by reference in its entirety.

### BACKGROUND

The present inventive concept relates to a semiconductor package.

As electronic devices become lighter and higher performance, the development of miniaturized and high-performance semiconductor packages is also required in the semiconductor package field. In particular, in order to realize high-performance and high-reliability of semiconductor packages, research and development on molded interposer (MIP) semiconductor packages to which chip on wafer (CoW) bonding is applied are continuously being conducted.

However, when performing an MIP level test, warpage or cracks may occur due to a difference in coefficients of thermal expansion (CTE) between a plurality of semiconductor chips and other materials constituting the MIP.

### SUMMARY

An aspect of the present inventive concept is to provide a semiconductor package having improved warpage.

According to an aspect of the present inventive concept, a semiconductor package includes a package substrate including first upper pads and first lower pads, located opposite to each other; an interposer substrate on the package substrate, the interposer substrate including second upper pads and second lower pads, located opposite to each other, and through-electrodes electrically connecting at least a portion of the second upper pads and at least a portion of the second lower pads; a chip structure on the interposer substrate, the chip structure including a connection pad on a lower surface of the chip structure; first bumps disposed between the interposer substrate and the chip structure, the first bumps electrically connecting the connection pad and the second upper pads; second bumps disposed between the interposer substrate and the package substrate, the second bumps electrically connecting the second lower pads and the first upper pads; connection bumps below the first lower pad of the package substrate; an underfill region disposed between the interposer substrate and the chip structure, the underfill region surrounding, with respect to a top-down view, each of the first bumps and including a side surface extending from a side surface of the chip structure to the interposer substrate; a molding member on the interposer substrate, the molding member surrounding, with respect to a top-down view, the chip structure and the underfill region; and a reinforcing member on the chip structure and the molding member, wherein a coefficient of thermal expansion of a first region including the chip structure and the molding member is lower than a coefficient of thermal expansion of the reinforcing member, and a coefficient of thermal expansion of a second region including the underfill region, the first bumps, and the interposer substrate is higher than the coefficient of thermal expansion of the first region.

According to an aspect of the present inventive concept, a semiconductor package includes a package substrate; an interposer substrate on the package substrate, the interposer substrate including upper pads and lower pads, located opposite to each other, through-electrodes electrically connecting at least a portion of the upper pads and at least a portion of the lower pads and a redistribution circuit connecting the upper pads and the through-electrodes; a chip structure on the interposer substrate, the chip structure including an upper surface, a lower surface, and a chip pad on the lower surface of the chip structure; first bumps disposed between, and electrically connecting, the interposer substrate and the chip structure; second bumps disposed between, and electrically connecting, the interposer substrate and the package substrate; an underfill region disposed between the interposer substrate and the chip structure, the underfill region surrounding, with respect to a top-down view, each of the first bumps; a molding member on the interposer substrate, the molding member surrounding, with respect to a top-down view, the chip structure to expose the upper surface of the chip structure; and a reinforcing member disposed on, and in contact with, the upper surface of the chip structure and an upper surface of the molding member, wherein a coefficient of thermal expansion of the reinforcing member is higher than a coefficient of thermal expansion of a region including the underfill region, the first bumps, and the interposer substrate.

According to an aspect of the present inventive concept, a semiconductor package includes a package substrate; an interposer substrate on the package substrate, the interposer substrate including upper pads and lower pads, located opposite to each other, through-electrodes electrically connecting at least a portion of the upper pads and at least a portion of the lower pads, and a redistribution circuit connecting the upper pads and the through-electrodes; a chip structure on the interposer substrate; first bumps disposed between, and electrically connecting, the interposer substrate and the chip structure, the first bumps comprising a height between 40 μm to 60 μm; second bumps disposed between, and electrically connecting, the interposer substrate and the package substrate; an underfill region disposed between the interposer substrate and the chip structure, the underfill region surrounding, with respect to a top-down view, each of the first bumps; a molding member on the interposer substrate, the molding member surrounding, with respect to a top-down view, the chip structure to expose at least a portion of an upper surface of the chip structure; and a reinforcing member on the chip structure and the molding member, wherein a coefficient of thermal expansion of the reinforcing member is 15×10⁻⁶K⁻¹ to 20×10⁻⁶K⁻¹, a coefficient of thermal expansion of a first region including the chip structure and the molding member is 5×10⁻⁶K⁻¹ to 10×10⁻⁶K⁻¹, a coefficient of thermal expansion of a second region including the underfill region, the first bumps, and the interposer substrate is 10×10⁻⁶K⁻¹ to 15×10⁻⁶K⁻¹.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1A is a side cross-sectional view illustrating a semiconductor package according to an embodiment. FIG. 1B is a plan view illustrating a portion of a configuration of the semiconductor package of FIG. 1A.

FIG. 2 is a cross-sectional view illustrating a semiconductor package according to an embodiment.

FIG. 3A and FIG. 3B are cross-sectional views illustrating a principle of relieving stress applied to a package by a reinforcing member having a high coefficient of thermal expansion.

FIG. 4A to FIG. 4E are cross-sectional views schematically illustrating a manufacturing process of a semiconductor package according to an embodiment.

FIG. 5A is a perspective view schematically illustrating a semiconductor package according to an embodiment, and FIG. 5B is a cross-sectional view illustrating a cross-section according to line II-II′.

FIG. 6 is a cross-sectional view of a semiconductor package according to an embodiment.

FIG. 7 is a cross-sectional view of a semiconductor package according to an embodiment.

FIG. 8 is a cross-sectional view of a semiconductor package according to an embodiment.

FIG. 9 is a cross-sectional view of a semiconductor package according to an embodiment.

### DETAILED DESCRIPTION

Hereinafter, preferred embodiments will be described with reference to the attached drawings. Spatially relative terms, such as “beneath,” “below,” “lower,” “above,” “upper,” “top,” “bottom,” “front,” “rear,” and the like, may be used herein for ease of description to describe positional relationships, such as illustrated in the figures, for example. It will be understood that the spatially relative terms encompass different orientations of the device in addition to the orientation depicted in the figures.

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary.

In addition, ordinal numbers such as “first,” “second,” “third,” and the like may be used as labels for specific elements, operations, directions, or the like to distinguish various elements, operations, directions, or the like. Terms not described using “first,” “second,” and the like in the specification may still be referred to as “first” or “second” in the claims. In addition, terms referenced by a specific ordinal number (e.g., “first” in a specific claim) may be described elsewhere with a different ordinal number (e.g., “second” in the specification or another claim).

As used herein, components described as being “electrically connected” are configured such that an electrical signal can be transferred from one component to the other (although such electrical signal may be attenuated in strength as it is transferred and may be selectively transferred).

It will be understood that when an element is referred to as being “connected” or “coupled” to or “on” another element, it can be directly connected or coupled to or on the other element or intervening elements may be present. In contrast, when an element is referred to as being “directly connected,” “directly attached,” “directly joined,” or “directly coupled” to another element, or as “contacting” or “in contact with” another element (or using any form of the word “contact”), there are no intervening elements present at the point of contact.

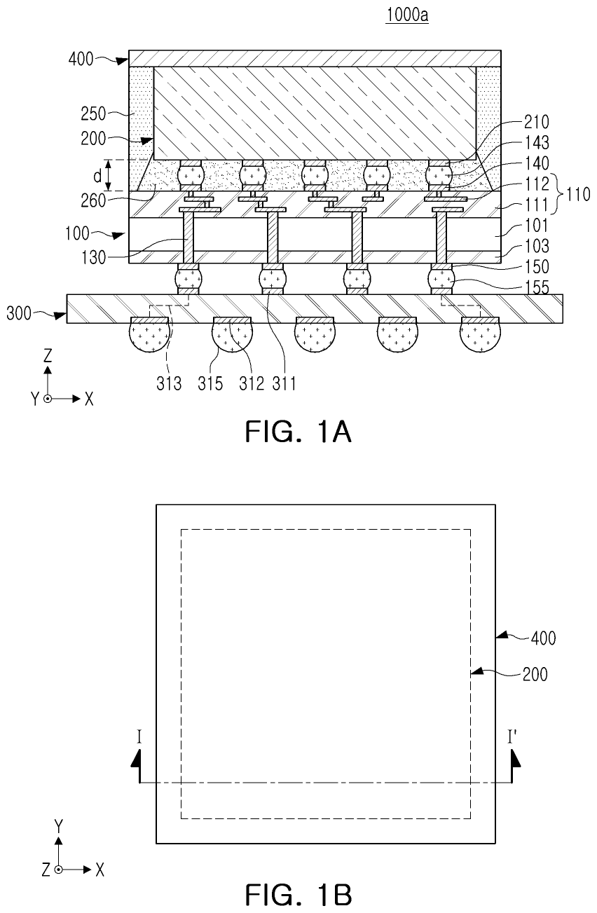

FIG. 1A is a side cross-sectional view illustrating a semiconductor package 1000a according to an embodiment. FIG. 1B is a plan view illustrating a portion of a configuration of the semiconductor package 1000a of FIG. 1A. FIG. 1A is a cross-sectional view of a portion of the configuration of FIG. 1B, taken along line I-I′.

Referring to FIGS. 1A and 1B, a semiconductor package 1000a according to an embodiment may include a package substrate 300, an interposer substrate 100, a chip structure 200, an underfill region 260, a molding member 250, and a reinforcing member 400.

The semiconductor package 1000a according to an embodiment may be divided into three regions according to a coefficient of thermal expansion. Specifically, there may be a first region including the chip structure 200, and the molding member 250, a second region including the underfill region 260, first bumps 143, and the interposer substrate 100, and a third region including the reinforcing member 400.

The package substrate 300 may be a semiconductor package substrate including a printed circuit board (PCB), a ceramic substrate, a glass substrate, a tape wiring substrate, or the like. The package substrate 300 may include first lower pads 312, first upper pads 311, and a first redistribution circuit 313.

The first lower pads 312 and the first upper pads 311 may be pads located opposite to each other. The first lower pads 312 may be located at a lower surface of the package substrate 300, and the first upper pads 311 may be located at an upper surface of the package substrate 300. The first lower pads 312 may form a portion of the lower surface of the package substrate 300 and the first upper pads 311 may form a portion of the upper surface of the package substrate 300. The first lower pads 312 and the first upper pads 311 may be formed of at least one metal or an alloy of two or more metals selected from the group consisting of copper (Cu), aluminum (Al), nickel (Ni), silver (Ag), gold (Au), platinum (Pt), tin (Sn), lead (Pb), titanium (Ti), chromium (Cr), palladium (Pd), indium (In), and zinc (Zn). While FIG. 1A illustrates the first upper pads 311 as protruding outwardly from an upper surface of the package substrate 300, the first upper pads 311 may, instead, be co-planar with the upper surface of the package substrate 300 (e.g., as shown with respect to first lower pads 312 and the lower surface of the package substrate 300). The first lower pads 312 and the first upper pads 311 may be electrically connected to each other through the first redistribution circuit 313. The first redistribution circuit 313 may be wiring formed of one or layers of conductive patterns that interconnect to each other and the first lower pads 312 and the first upper pads 311 with conductive vias. The first redistribution circuit 313 may be formed of a material, similar to that of the first lower pads 312 and the first upper pads 311.

The first upper pads 311 may be connected to second bumps 155 disposed between the interposer substrate 100 and the package substrate 300. The first lower pads 312 may be connected to connecting bumps 315 disposed below the package substrate 300. The connecting bumps 315 may be solder balls formed of, for example, tin (Sn) or an alloy including tin (Sn). In some embodiments, an underfill layer surrounding the second bumps 155 may be formed between the package substrate 300 and the interposer substrate 100.

The interposer substrate 100 may include a substrate 101, a lower protective layer 103, second upper pads 140, second lower pads 150, an interconnection structure 110, and a through-via 130.

The substrate 101 may be, for example, a silicon substrate, an organic substrate, a plastic substrate, or a glass substrate. In the case that the substrate 101 is a silicon substrate, the interposer substrate 100 may be referred to as a silicon interposer. In the case that the substrate 101 is an organic substrate, the interposer substrate 100 may be referred to as an organic interposer. The substrate 101 may not include any active electrical devices (e.g., transistors or logic devices formed of interconnected transistors).

The lower protective layer 103 may be disposed on a lower surface of the substrate 101, and the second lower pads 150 may be disposed on the lower protective layer 103. The second lower pads 150 may be connected to the through-via 130. The chip structure 200 may be electrically connected to the package substrate 300 through the second bumps 155 disposed below the second lower pads 150.

The interconnection structure 110 may be disposed on the upper surface of the substrate 101, and may include dielectric layers 111 and a wiring structure 112 (i.e., wires) as a single-layer or multilayers. When the interconnection structure 110 is formed of the multilayer wiring structure, wires may be formed of corresponding wiring patterns of adjacent layers separated from one another by a corresponding one of the dielectric layers and connected to each other through a contact-via. The interconnection structure 110 may form a redistribution layer.

The through-via 130 may extend from an upper surface of the substrate 101 to the lower surface of the substrate 101, to penetrate through the substrate 101. The through-via 130 may extend into the dielectric layers 111 of the interconnection structure 110, and may be electrically connected to the wiring structure 112 of the interconnection structure 110. When the substrate 101 is silicon, the through-via 130 may be referred to as a through silicon via (TSV). In an alternative example, the interposer substrate 100 may include only an interconnection structure therein (e.g., interconnection structure 110), and may not include any through-vias, the substrate 101 and/or the lower protective layer 103.

The second lower pads 150 may be disposed at a lower surface of the interposer substrate 100, and the second upper pads 140 may be disposed at an upper surface of the interposer substrate 100. For example, the second lower pads 150 may be in contact with the lower protective layer 103, while the second upper pads 140 may be in contact with the dielectric layers 111. While FIG. 1A illustrates the second lower pads 150 as protruding outwardly from a lower surface of the lower protective layer 103, the second lower pads 150 can, instead, be co-planar with or below the lower surface of the lower protective layer 103. Likewise, the second upper pads 140 are illustrated as protruding outwardly from an upper surface of the dielectric layers 111, the second upper pads 140 can, instead, be co-planar with or below the upper surface of the dielectric layers 111. The second lower pads 150 and the second upper pads 140 may be formed of at least one metal or an alloy of two or more metals selected from the group consisting of copper (Cu), aluminum (Al), nickel (Ni), silver (Ag), gold (Au), platinum (Pt), tin (Sn), lead (Pb), titanium (Ti), chromium (Cr), palladium (Pd), indium (In), and zinc (Zn). The second upper pads 140 and the second lower pads 150 may be electrically connected through the through-via 130 and the wiring structure 112 of the interconnection structure 110. For example, the second upper pads 140 can be electrically connected to the wiring structure 112 of the interconnection structure 110, and the second lower pads 150 can be electrically connected to the through-vias 130.

With respect to a top-down view, an area of the second lower pads 150 may be equal to or greater than an area of the second upper pads 140. The area may comprise a diameter of the second upper pads 140 or the second lower pads 150, for example, when the second upper pads 140 and/or the second lower pads 150 comprise a circular or spherical shape. When the area of the second upper pads 140 is equal to the area of the second lower pads 150, a height of the first bumps 143 may also increase in proportion to the area of the second upper pads 140. Therefore, a gap between the chip structure 200 and the interposer substrate 100 may increase. The gap between the chip structure 200 and the interposer substrate 100 may increase to increase a volume of the underfill region 260 having a high coefficient of thermal expansion, and increase a ratio occupied by the underfill region 260. This may cause a difference in coefficients of thermal expansion between the first region and the second region. As used herein, the term height can comprise a dimension or distance in a vertical direction, for example, a Z-direction.

The chip structure 200 may include, for example, a logic chip such as a central processor (CPU), a graphics processor (GPU), a field programmable gate array (FPGA), an application processor (AP), a digital signal processor, an encryption processor, a microprocessor, a microcontroller, an analog-to-digital converter, an application-specific IC (ASIC), or the like, or a memory chip including a volatile memory such as a dynamic RAM (DRAM), a static RAM (SRAM), or the like, or a non-volatile memory such as a phase change RAM (PRAM), a magnetic RAM (MRAM), a resistive RAM (RRAM), or a flash memory, or the like. The chip structure 200 may be a chip or a stack of semiconductor chips. In some examples, the upper and lower surfaces of the chip structure may correspond to surfaces of a semiconductor chip or chips. For example, when the chip structure is a stack of semiconductor chips, the chip structure 200 may have an upper surface including a surface of the uppermost one of the stack of semiconductor chips and may have a lower surface including a surface of the lowermost one of the stack of semiconductor chips.

The first bumps 143 may be disposed between the chip structure 200 and the interposer substrate 100, and may electrically connect connection pads 210 and the second upper pads 140, opposite to each other. The connection pads 210 may be chip pads of a semiconductor chip forming the chip structure (e.g., a chip pads of a semiconductor chip when the chip structure 200 is a single semiconductor chip, or chip pads of the lowermost chip when the chip structure 200 is a stack of chips). The various chip pads described herein may comprise electrically conductive terminals that are connected to internal wiring of the corresponding semiconductor chip, and may transmit signals and/or supply voltages between an internal wiring and/or internal circuit of the corresponding semiconductor chip and an external source. For example, chip pads of a semiconductor chip may electrically connect to and transmit supply voltages and/or signals between an integrated circuit of the semiconductor chip and a device to which the semiconductor chip is connected.

The first bumps 143 may include a solder portion (not illustrated). The solder portion (not illustrated) may include, for example, tin (Sn) or an alloy including tin (Sn) (e.g., Sn—Ag—Cu). Though the first bumps 143 are illustrated as solder balls in FIG. 1A, the first bumps 143 can also comprise a pillar, a post, etc.

A cross-sectional dimension, with respect to a top-down view, of each of the first bumps 143 may be about 60 μm to 80 μm. The cross-sectional dimension of the first bumps 143 may comprise a diameter, for example, when the first bumps 143 comprise a circular or spherical shape. A gap between the first bumps 143 may be about 100 μm to 150 μm, with the gap measured between two adjacent first bumps 143 with no intervening first bumps within the gap between the two adjacent bumps 143. For example, the gap between the first bumps 143 may be measured in a direction transverse to the height in the vertical direction (e.g., Z-direction), with the gap between the first bumps 143 measured in the X-direction or the Y-direction. As the number and sizes of the first bumps 143 and the second bumps 155 increase, a ratio of metal in the semiconductor package 1000a may increase. As a ratio of metal having a high coefficient of thermal expansion increases, a difference in coefficients of thermal expansion between the first region and the second region may increase. For example, the second region comprises the first bumps 143, and as the first bumps 143 increase in size (e.g., diameter) and/or number (e.g., with a decreasing gap between adjacent bumps), the coefficient of thermal expansion of the second region may increase, thus increasing a difference in the coefficients of thermal expansion between the first region and the second region. Therefore, the semiconductor package 1000a may receive a large amount of bending stress due to the difference in coefficients of thermal expansion between the first region and the second region.

The second bumps 155 may be disposed between the interposer substrate 100 and the package substrate 300, and may electrically connect the second lower pads 150 and the first upper pads 311, opposite to each other. The second bumps 155 may include a solder portion (not illustrated). Though the second bumps 155 are illustrated as solder balls in FIG. 1A, the second bumps 155 can also comprise a pillar, a post, etc. The solder portion (not illustrated) may include, for example, tin (Sn) or an alloy including tin (Sn) (e.g., Sn—Ag—Cu). The coefficients of thermal expansion of the first bumps 143 and the second bumps 155 may be about 15×10⁻⁶K⁻¹ to 25×10⁻⁶K⁻¹.

The underfill region 260 may be disposed between the chip structure 200 and the interposer substrate 100. The underfill region 260 may fill a gap between the chip structure 200 and the interposer substrate 100, and may surround at least a portion of the connection pad 210 and each of the first bumps 143. The underfill region 260 may be in contact with a lower surface of the chip structure 200 and an upper surface of the dielectric layers 111, and may surround the first bumps 143. The underfill region 260 may include a side surface extending from a side surface of the chip structure 200 to the interposer substrate 100. The underfill region 260 may be in contact with a side surface of each of the first bumps 143. The underfill region 260 may be formed using an insulating resin, such as an epoxy resin. The underfill region 260 may have a capillary underfill (CUF) structure, but is not limited thereto. According to an embodiment, the underfill region 260 may have a molded underfill (MUF) structure integrated with the molding member 250 covering the chip structure 200. The underfill region 260 surrounds the first bumps 143, and a coefficient of thermal expansion of the underfill region 260 may be about 15×10⁻⁶K⁻¹ to 25×10⁻⁶K⁻¹.

The underfill region 260 filling the space between the chip structure 200 and the interposer substrate 100 may comprise a height corresponding to a height of the between the chip structure 200 and the dielectric layers 111. For example, an underfill height d may be defined as a distance between a lower surface of the chip structure 200 and the upper surface of the interposer substrate 100 in the vertical direction (e.g., Z-direction). As illustrated in FIG. 1A, when the second upper pads 140 protrude outwardly from an upper surface of the dielectric layers 111 and the connection pads 210 protrude outwardly from a lower surface of the chip structure 200, the underfill height d can be understood as a sum of a height of the second upper pads 140, a height of the first bump 143, and a height of the connection pad 210. Alternatively, when the second upper pads 140 are co-planar with the upper surface of the dielectric layers 111 and the connection pads 210 are co-planar with the lower surface of the chip structure 200, the underfill height d may be equal to a height of the first bumps 143. The underfill height d, corresponding to a gap or distance between the chip structure 200 and the interposer substrate 100, may be about 40 μm to 60 μm.

A height of the first region in the vertical direction may be about 500 μm to 700 μm. For example, a height of the molding member 250 in the vertical direction, encapsulating the side surface of the chip structure 200 and the underfill region 260, may be about 500 μm to 700 μm. A height of the second region in the vertical direction may be about 90 μm to 210 μm. Therefore, a height obtained by adding a distance between the lower surface of the chip structure 200 and the upper surface of the interposer substrate 100 and a height of the interposer substrate 100 may be about 90 μm to 210 μm.

In an example embodiment, an increase in volume of the underfill region 260 may increase the coefficient of thermal expansion of the second region, thereby further degrading warpage characteristics of the package. Specifically, when the volume of the underfill region 260 increases, the coefficient of thermal expansion of the second region may increase, which increases a difference between the coefficient of thermal expansion of the first region and the coefficient of thermal expansion of the second region. As a result, the increasing difference in coefficients of thermal expansion between the first region and the second region can lead to increased warpage.

Referring to FIG. 1A, as the underfill height d increases, a volume of the underfill filling the space between the chip structure 200 and the interposer substrate 100 may also increase. Therefore, as the underfill height d increases, the coefficient of thermal expansion of the second region may increase to further degrade warpage characteristics of the package. In this case, a ratio of the underfill height d relative to the height of the first region in the vertical direction may be used to consider warpage due to a difference in coefficients of thermal expansion. As the ratio of the underfill height d relative to the height of the first region in the vertical direction increases, a volume of the underfill may increase. Therefore, warpage due to the difference in the coefficient of thermal expansion may be further worsened. The ratio of the underfill height d relative to the height of the first region in the vertical direction may be about 0.05 or more, and as the ratio of the underfill height d relative to the height of the first region in the vertical direction increases, warpage due to the difference in the coefficient of thermal expansion may be worsened.

The molding member 250 may be disposed on the interposer substrate 100, and may surround and encapsulate the chip structure 200 and the underfill region 260 to expose at least a portion of the upper surface of the chip structure 200. Specifically, the molding member 250 may contact and surround the side surfaces of the chip structure 200 and the side surfaces of the underfill region 260, and may expose the upper surface of the chip structure 200 since the molding member 250 may not cover the upper surface of the chip structure 200. Therefore, an upper surface of the molding member 250 may be located on a level, equal to a level of the upper surface of the chip structure 200 for example, with the upper surface of the molding member 250 being co-planar with the upper surface of the chip structure 200. The molding member 250 may be formed from an insulating material, and for example, an epoxy molding compound (EMC) may be used. A coefficient of thermal expansion of the molding member 250 may be about 5×10⁻⁶K⁻¹ to 15×10⁻⁶K⁻¹.

The reinforcing member 400 may have a coefficient of thermal expansion that is higher than the coefficient of thermal expansion of the first region including the chip structure 200 and the molding member 250. As such, the reinforcing member 400 can offset bending stress caused by the difference in coefficients of thermal expansion between the first region and the second region including the underfill region 260, the first bumps 143, and the interposer substrate 100.

A height of the reinforcing member 400 may range from about 0.5 μm to about 5 μm. The reinforcing member 400 may be formed from at least one of nickel (Ni), copper (Cu), or aluminum (Al), but is not limited thereto. The reinforcing member 400 may be in contact with the upper surface of the molding member 250 and the upper surface of the chip structure 200 at the same time, and the upper surface of the molding member 250 may be located on a level, equal to a level of the upper surface of the chip structure 200, for example, with the upper surface of the molding member 250 being co-planar with the upper surface of the chip structure 200. A side surface of the reinforcing member 400, the side surface of the molding member 250, and the side surface of the interposer substrate 100 may be on the same surface, for example, with the side surface of the reinforcing member 400, the side surface of the molding member 250, and the side surface of the interposer substrate 100 being co-planar with one another.

The coefficient of thermal expansion of the first region may be lower than the coefficient of thermal expansion of the second region. The difference in the coefficients of thermal expansion of the first region and the second region may cause bending stress in the semiconductor package. The coefficient of thermal expansion of the reinforcing member 400 may be higher than the coefficients of thermal expansion of the first region and the second region. Since the reinforcing member 400 having a high coefficient of thermal expansion may be disposed on the upper surface of the molding member 250 and the upper surface of the chip structure 200, the reinforcing member 400 can alleviate the difference in the coefficients of thermal expansion of the first region and the second region. The coefficient of thermal expansion of the reinforcing member may be about 15×10⁻⁶K⁻¹ to 20×10⁻⁶K⁻¹, the coefficient of thermal expansion of the first region may be about 5×10⁻⁶K⁻¹ to 10×10⁻⁶K⁻¹, and the coefficient of thermal expansion of the second region may be about 10×10⁻⁶K⁻¹ to 15×10⁻⁶K⁻¹.

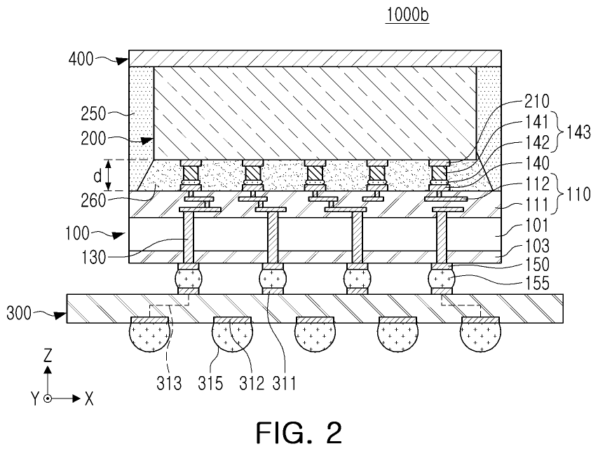

FIG. 2 is a cross-sectional view illustrating a semiconductor package 1000b according to an embodiment.

Referring to FIG. 2, a semiconductor package 1000b according to an embodiment may have the same or similar features as those described with reference to FIGS. 1A and 1B. For example, features such as the interposer substrate 100, the interconnection structure 110, the chip structure 200, the molding member 250, the package substrate 300, the reinforcing member 400 of the semiconductor package 1000b of FIG. 2 may be the same as the semiconductor package 1000a of FIGS. 1A and 1B. However, the first bumps 143 of the semiconductor package 1000b may include a pillar portion 141 and a solder portion 142, for example, with the first bump 143 formed with the pillar portion 141 and the solder portion 142.

Referring to FIG. 2, the first bumps 143 may be disposed between the chip structure 200 and the interposer substrate 100, and may electrically connect the connection pad 210 and second upper pads 140, opposite to each other. The first bumps 143 may include the pillar portion 141 disposed below the connection pad 210, and the solder portion 142 disposed below the pillar portion 141 and contacting the second upper pads 140. The pillar portion 141 may have a cylindrical shape or a polygonal pillar shape. The pillar portion 141 may be formed from, for example, at least one of aluminum (Al), copper (Cu), nickel (Ni), tungsten (W), platinum (Pt), or gold (Au). The pillar portion 141 may include a seed layer (not illustrated) disposed on the connection pad 210. The solder portion 142 may be formed from, for example, tin (Sn) or an alloy including tin (Sn) (e.g., Sn—Ag—Cu).

An underfill filling a space between a chip and an interposer may be formed to have a height corresponding to a height of a bump. An underfill height d may be defined as a distance between a lower surface of the chip structure 200 and an upper surface of the interposer substrate 100. As illustrated in FIG. 2, the underfill height d can be understood as the vertical distance between the upper surface of the uppermost one of the dielectric layers 111 and the major surface (the planar surface of a layer forming the majority) of the bottom surface of the chip structure 200. For example, the underfill height d may correspond to a sum of a height of the second upper pads 140, a height of the first bump 143, and a height of the connection pad 210. For example, when the second upper pads 140 are co-planar with the upper surface of the dielectric layers 111, and the connection pads 210 are co-planar with the remaining portion of the lower surface of the chip structure 200, the underfill height d may be equal to a height of the first bumps 143. The underfill height d may be about 15 μm to 30 μm. A diameter of the first bump 143 may be about 30 μm to 50 μm. A gap between the first bumps 143 may be about 30 μm to 50 μm, with the gap measured between two adjacent first bumps 143 with no intervening first bumps within the gap between the two adjacent bumps 143. The gap between the first bumps 143 may be measured in a direction transverse to the height in the vertical direction (e.g., Z-direction), with the gap between the first bumps 143 measured in the X-direction or the Y-direction.

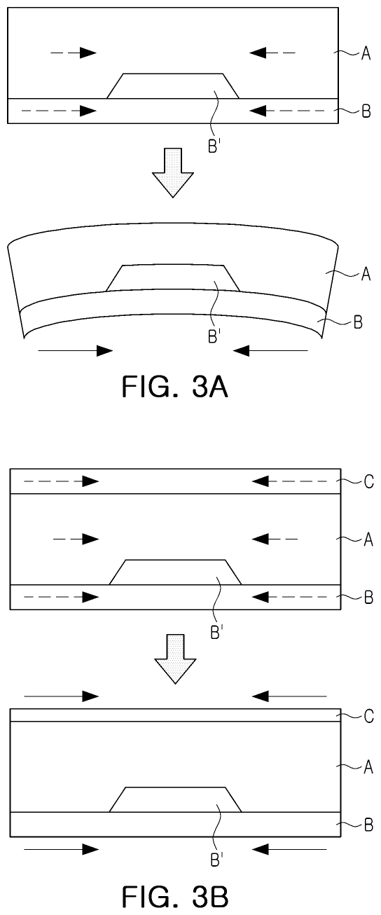

FIGS. 3A and 3B are cross-sectional views illustrating a principle of relieving stress applied to a package by a reinforcing member having a high coefficient of thermal expansion.

Referring to FIGS. 1A and 3A, warpage may occur due to a difference in coefficients of thermal expansion of a semiconductor package between a first region A including a chip structure 200 and a molding member 250, and a second region B including an underfill region B′ and an interposer substrate 100. The underfill region B′ can be understood as a region including an underfill region 260 and first bumps 143. In the drawings, magnitudes (degree of thermal deformation) of a coefficient of thermal expansion of the first region A and a coefficient of thermal expansion of the second region B may be indicated by a dotted arrow line (see an upper drawing of FIG. 3A). Since the coefficient of thermal expansion of the second region B is higher than the coefficient of thermal expansion of the first region A, shrinkage of the second region B may be relatively large after a level test is performed, and bending stress such as a solid arrow line may occur (see a lower drawing of FIG. 3A).

Specifically, as a gap between the chip structure 200 and the interposer substrate 100 increases according to a height of the first bumps 143, a ratio occupied by the underfill region B′ may also increase. Therefore, the coefficient of thermal expansion of the second region B including the underfill region B′ may also increase. For example, as the ratio of the underfill region B′ increases, the difference in coefficients of thermal expansion between the first region A and the second region B may increase. As a result, as the coefficient of thermal expansion of the second region B increases, the difference between the coefficient of thermal expansion of the first region A and the coefficient of thermal expansion of the second region B may increase, and as illustrated in the drawings, shrinkage of the second region B may appear significantly, with shrinkage of the second region B greater than shrinkage of the first region A, thus causing warpage of the semiconductor package.

Referring to FIG. 3B, in an embodiment, a reinforcing member C may be further included on an upper portion of the first region A. The reinforcing member C may be equivalent to the reinforcing member 400. A coefficient of thermal expansion of the reinforcing member C may be higher than the coefficient of thermal expansion of the first region A (see an upper drawing of FIG. 3B). In an example embodiment, the coefficient of thermal expansion of the reinforcing member C may be 0.75 times or more the coefficient of thermal expansion of the underfill region B′, for example, in a range of 0.75 to 1.25 times, or the like. When the coefficient of thermal expansion of the reinforcing member C is less than 0.75 times the coefficient of thermal expansion of the underfill region B′, an effect of offsetting the coefficient of thermal expansion by the reinforcing member C will be insignificant, and warpage may not be alleviated. When the coefficient of thermal expansion of the reinforcing member C is 1.25 times or more the coefficient of thermal expansion of the underfill region B′, bending stress will occur due to a difference in coefficients of thermal expansion between the reinforcing member C and the first region A, and thus shrinkage of the reinforcing member C will occur significantly. Bending stress generated by the shrinkage of the reinforcing member C disposed opposite to the second region B, and bending stress generated in the second region B may be offset from each other (see the lower drawing of FIG. 3B). Therefore, stress acting on the first region A may be relieved, thereby improving bending characteristics of the semiconductor package.

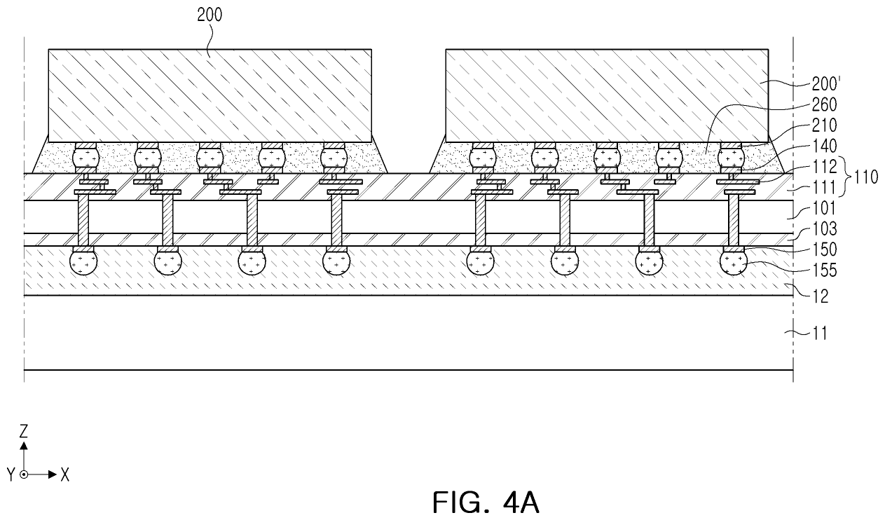

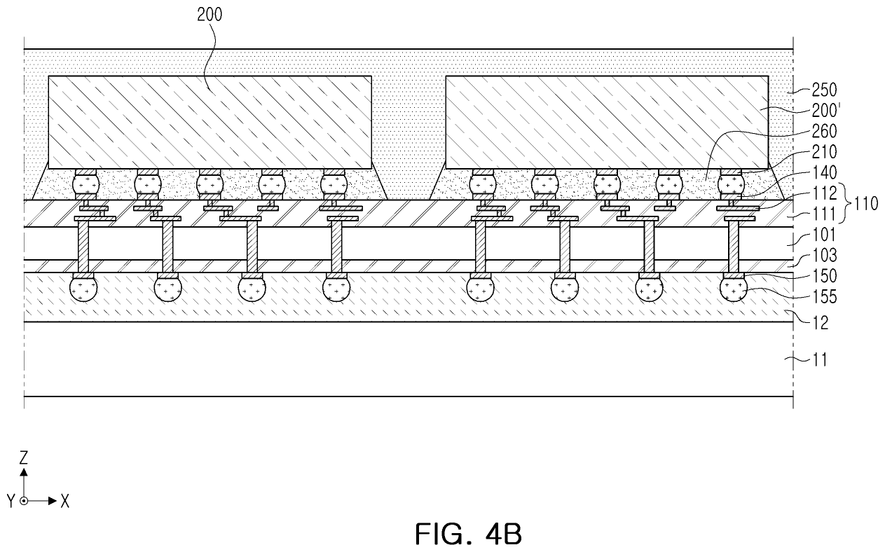

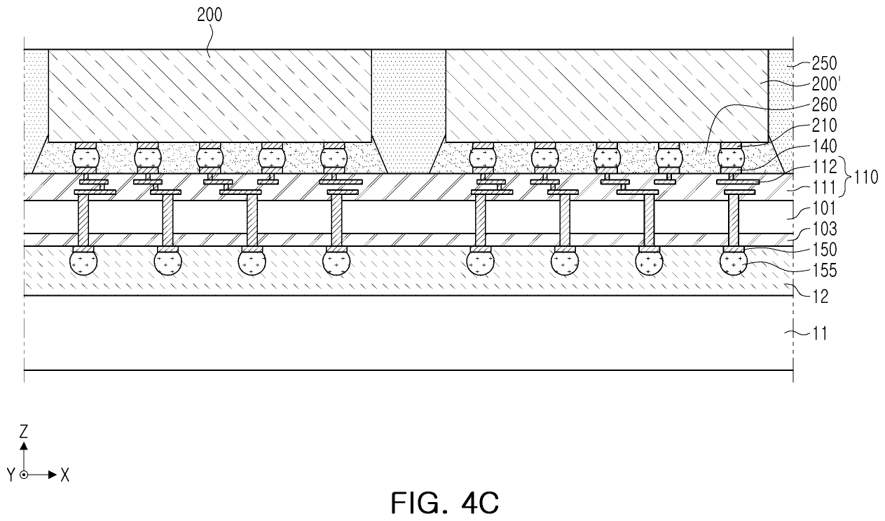

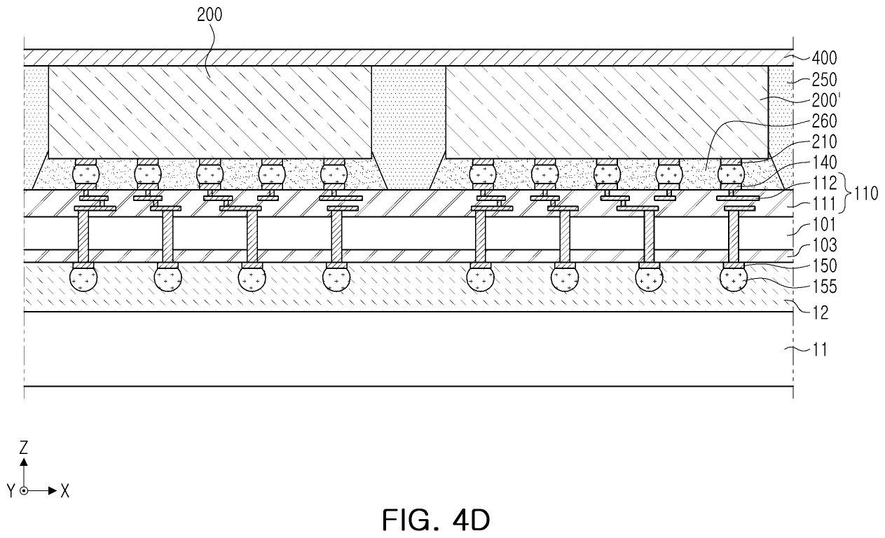

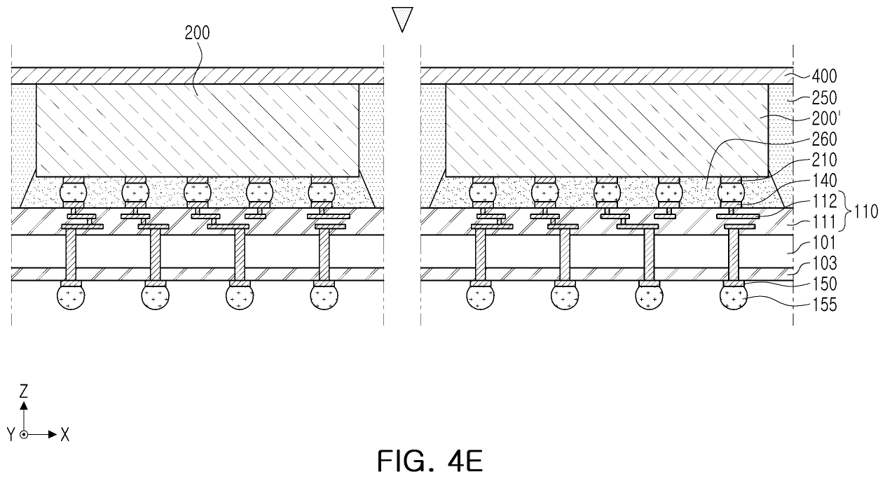

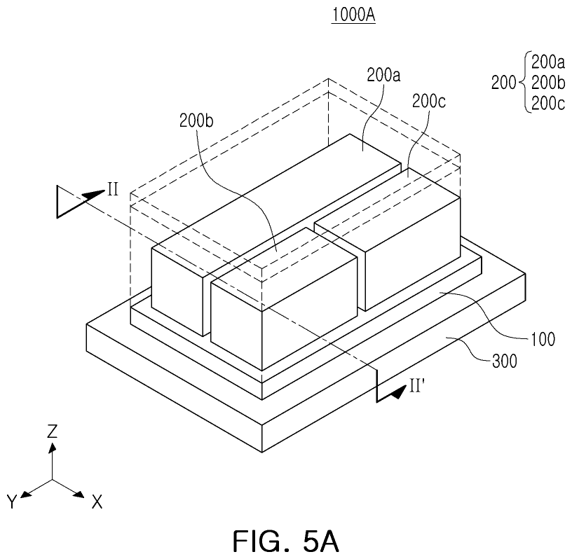

FIGS. 4A to 4E are cross-sectional views schematically illustrating a manufacturing process of a semiconductor package according to an embodiment.

Referring to FIG. 4A, a plurality of chip structures 200 and 200′ may be mounted on an upper surface of an interposer substrate 100. The plurality of chip structures 200 and 200′ may be mounted on the interposer substrate 100 by a flip chip bonding method. Specifically, a heat-compression bonding process may be performed to mount the plurality of chip structures 200 and 200′ on the interposer substrate 100. The underfill region 260 surrounding the first bumps 143 may be formed by a heat-compression bonding process. As a height of the first bumps 143 increases, a volume of the underfill region 260 may increase. Therefore, a ratio of the underfill region 260 may be controlled by controlling the height of the first bumps 143.

Referring to FIG. 4B, a molding member 250 may be formed on the interposer substrate 100 and the plurality of chip structures 200 and 200′ by an encapsulation process. The molding member 250 may be formed to cover the plurality of chip structures 200 and 200′.

Referring to FIG. 4C, a portion of an upper portion of the molding member 250 may be removed by using a polishing process. The molding member 250 may be formed to have a desired height by applying the polishing process. The molding member 250 may be formed with a height such that a portion of the plurality of chip structures 200 and 200′ protrudes. The molding member 250 may encapsulate side surfaces of the plurality of chip structures 200 and 200′ such that at least a portion of upper surfaces of the plurality of chip structures 200 and 200′ is exposed, with the molding member 250 not covering the upper surfaces of the plurality of chip structures 200 and 200′. An upper surface of the molding member 250 may be located on a level, equal to a level of the upper surfaces of the plurality of chip structures 200 and 200′, for example, with the upper surface of the molding member 250 co-planar with the upper surfaces of the plurality of chip structures 200 and 200′. The polishing process may use a chemical mechanical polishing (CMP) process, an etch-back process, or a combination thereof.

Referring to FIG. 4D, the reinforcing member 400 may be formed on the upper surface of each of the plurality of chip structures 200 and 200′ and the upper surface of the molding member 250. The reinforcing member 400 may be formed using a spray coating process, a physical vapor deposition (PVD), a chemical vapor deposition, or the like. The reinforcing member 400 may be formed to have a height of about 0.5 μm to about 5 μm. When a ratio of the underfill region 260 having a high coefficient of thermal expansion increases, the reinforcing member 400 may be formed thick with a greater height to offset the increased volume of the underfill region 260, and when the ratio of the underfill region 260 decreases, the reinforcing member 400 may be formed thinner with a reduced height to offset the volume of the underfill region 260. In addition, when a ratio of metal of the semiconductor package increases, the reinforcing member 400 may be formed thick with a greater height to offset the increased volume of the metal, and when the ratio of metal decreases, the reinforcing member 400 may be formed thinner with a reduced height to offset the volume of the metal. The present inventive concept may control a ratio of metal of the first region and metal of the second region by controlling the height of the reinforcing member 400, and may offset a difference in coefficients of thermal expansion between the first region and the second region.

The reinforcing member 400 may be formed of a metal having a coefficient of thermal expansion that is higher than that of the first region including the chip structure 200 and the molding member 250. Likewise, the coefficient of thermal expansion of the reinforcing member 400 is higher than a coefficient of thermal expansion of the second region including the interposer substrate 100, the first bumps 143, and the underfill region 260. The reinforcing member 400 may include, for example, any one of nickel (Ni), copper (Cu), or aluminum (Al). The coefficient of thermal expansion of the reinforcing member 400 may be about 15×10⁻⁶K⁻¹ to 20×10⁻⁶K⁻¹.

Referring to FIG. 4E, a carrier substrate 11 for temporarily fixing and supporting the interposer substrate 100 may be removed. In addition, an adhesive layer 12 for fixing the interposer substrate 100 to the carrier substrate 11 may also be removed.

The interposer substrate 100, the molding member 250, and the reinforcing member 400 may be cut, and the plurality of chip structures 200 and 200′ may be separated. Therefore, individual package semiconductors may be formed.

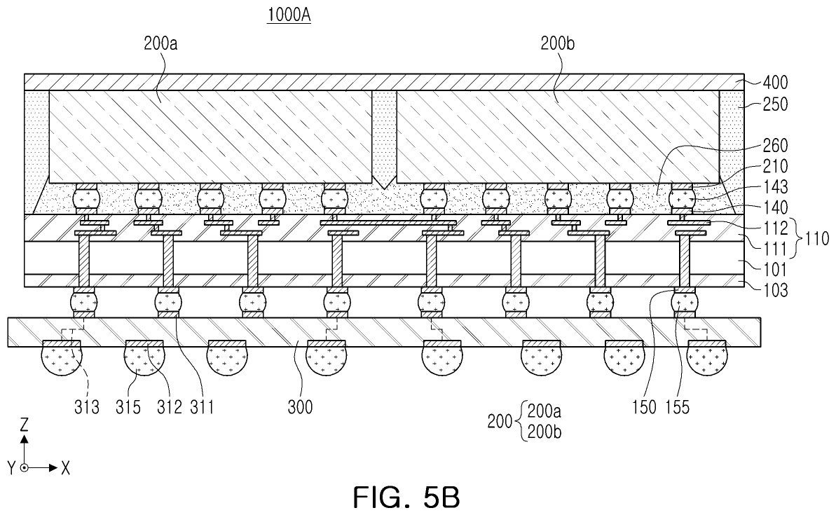

FIG. 5A is a perspective view schematically illustrating a semiconductor package 1000A according to an embodiment, and FIG. 5B is a cross-sectional view illustrating a cross-section according to line II-II′.

Referring to FIGS. 5A and 5B, a semiconductor package 1000A according to an embodiment may have the same or similar features as those described with reference to FIGS. 1A and 2, except that a plurality of chip structures 200a, 200b and 200c are provided. Each chip structure 200a, 200b and 200c may be the same as chip structure 200 (e.g., a chip or a stack of chips) described elsewhere herein and be connected to the interposer substrate 100 as described elsewhere herein.

Referring to FIGS. 5A and 5B, the semiconductor package 1000A in an embodiment may include the package substrate 300, the interposer substrate 100, and a plurality of chip structures 200, for example, a first chip structure 200a, a second chip structure 200b, a third chip structure 200c, etc. The plurality of chip structures 200 may be electrically connected to each other via the interposer substrate 100, for example, with the first chip structure 200a electrically connected to the second chip structure 200b via the interposer substrate 100.

Each chip structure 200 may include an integrated circuit (IC) and a semiconductor wafer formed of a semiconductor element such as silicon, germanium, or the like, or a compound semiconductor such as silicon carbide (SiC), gallium arsenide (GaAs), indium arsenide (InAs), and indium phosphide (InP). Each chip structure 200 may be a bare semiconductor chip without a separate bump or a separate wiring layer formed thereon, but is not limited thereto, and may also be a stack of chips, or a semiconductor package including a semiconductor chip or a plurality of chips.

The chip structures 200 may include a logic chip such as a central processor (CPU), a graphics processor (GPU), a field programmable gate array (FPGA), an application processor (AP), a digital signal processor, an encryption processor, a microprocessor, a microcontroller, an analog-to-digital converter, an application-specific IC (ASIC), or the like, or a memory chip including a volatile memory such as a dynamic RAM (DRAM), a static RAM (SRAM), or the like, or a non-volatile memory such as a phase change RAM (PRAM), a magnetic RAM (MRAM), a resistive RAM (RRAM), or a flash memory, or the like.

The plurality of chip structures 200a, 200b and 200c may be disposed on the interposer substrate 100. The plurality of chip structures 200a, 200b and 200c may be electrically connected to each other through the interconnection structure 110. The first chip structure 200a and the second chip structure 200b may include different types of semiconductor chips. For example, the first chip structure 200a may include a logic chip such as a central processor (CPU), a graphics processor (GPU), a field programmable gate array (FPGA), a digital signal processor, an encryption processor, a microprocessor, a microcontroller, an analog-to-digital converter, an ASIC, or the like, and the second chip structure 200b may include a memory chip such as a dynamic random access memory (DRAM), an SRAM, a PRAM, a ReRAM, an FeRAM, an MRAM, or a flash memory. According to an embodiment, the second chip structure 200b may be provided as a high-performance memory device such as a high bandwidth memory (HBM), a hybrid memory cube (HMC), or the like.

The interposer substrate 100 may be used for the purpose of converting or transmitting an input electrical signal between the package substrate 300 and the plurality of chip structures 200a, 200b and 200c. The interposer substrate 100 may not include active devices, such as transistors or logic circuits formed of interconnected transistors. In addition, according to an embodiment, the interconnection structure 110 may be disposed around a lower portion of a through-via 130. For example, a positional relationship between the interconnection structure 110 and the through-via 130 may be relative.

Second bumps 155 may electrically connect the package substrate 300 and the interposer substrate 100. The chip structures 200 may be electrically connected to the second bumps 155 through the wiring structure 112 of the interconnection structure 110 and the through-via 130. According to an embodiment, second lower pads 150 may be integrated, and may be connected together with the second bumps 155, such that the number of the second lower pads 150 may be greater than the number of the second bumps 155.

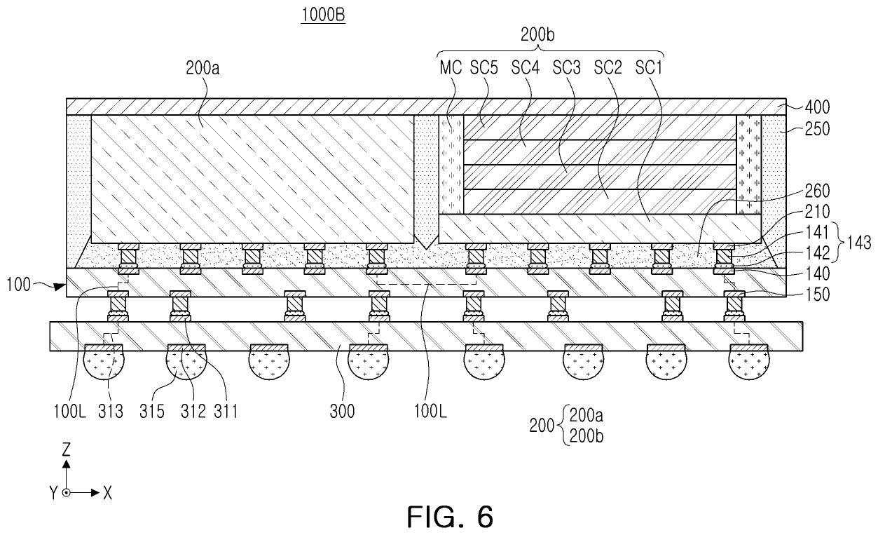

FIG. 6 is a cross-sectional view of a semiconductor package 1000B according to an embodiment. FIG. 6 may be an example of the embodiment of FIGS. 5A and 5B.

Referring to FIG. 6, a semiconductor package 1000B according to an example may have the same or similar features as those described with reference to FIGS. 5A and 5B. Therefore, redundant descriptions may be omitted.

The plurality of chip structures 200a and 200b may be disposed on an interposer substrate 100. The plurality of chip structures 200a and 200b may be electrically connected to each other through a redistribution circuit 100L (wiring of interposer substrate 100). The first chip structure 200a and the second chip structure 200b may include different types of semiconductor chips. For example, the first chip structure 200a may include a logic chip such as a central processor (CPU), a graphic processor (GPU), a field programmable gate array (FPGA), a digital signal processor, an encryption processor, a microprocessor, a microcontroller, an analog-to-digital converter, an ASIC, or the like, and the second chip structure 200b may include a memory chip such as a DRAM, an SRAM, a PRAM, a ReRAM, an FeRAM, an MRAM, or a flash memory. According to an embodiment, the second chip structure 200b may be provided as a high-performance memory device such as a high bandwidth memory (HBM), a hybrid memory cube (HMC), or the like.

The second chip structure 200b may include a stack of chips, for example, the plurality of semiconductor chips SC1, SC2, SC3, SC4, and SC5 and a mold layer MC. The plurality of semiconductor chips SC1, SC2, SC3, SC4, and SC5 may be provided in more or less numbers than those illustrated in the drawing. For example, the second chip structure 200b can comprise one or more semiconductor chips. The plurality of semiconductor chips SC1, SC2, SC3, SC4, and SC5 may be stacked in a vertical direction (Z direction) by a thermocompression bonding method or a hybrid bonding method. The plurality of semiconductor chips SC1, SC2, SC3, SC4, and SC5 may be interconnected through a through silicon via. The plurality of semiconductor chips SC1, SC2, SC3, SC4, and SC5 may include a buffer chip (e.g., SC1) and a plurality of memory chips (e.g., SC2, SC3, SC4, and SC5). The mold layer MC may be formed of an insulating material such as an epoxy molding compound (EMC), for example.

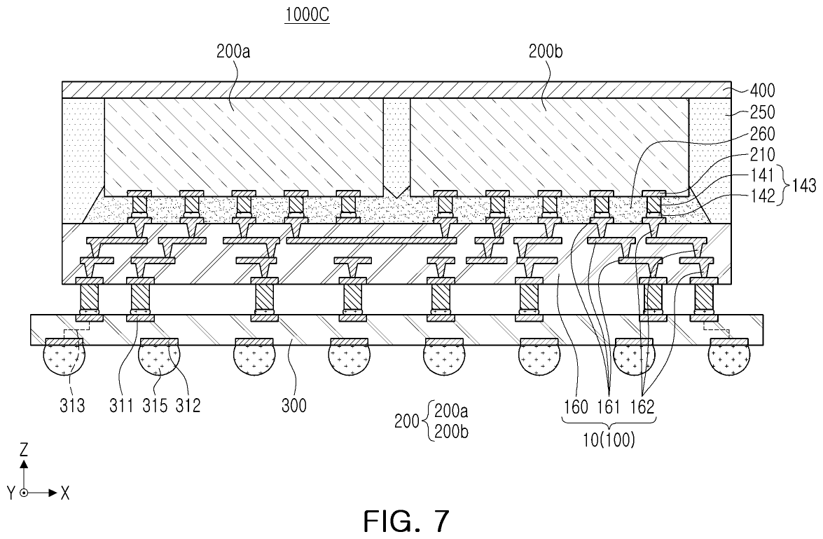

FIG. 7 is a cross-sectional view of a semiconductor package 1000C according to an embodiment.

Referring to FIG. 7, a semiconductor package 1000C according to an embodiment may have the same or similar features as those described with reference to FIGS. 1A to 6. Further details of an exemplary interposer substrate 10 of a first type is provided. The first interposer substrate 10 can be understood to be an example of the interposer substrate 100 described elsewhere herein (e.g., with reference to FIGS. 1A to 6 and 9).

The first interposer substrate 10 may include an insulating layer 160, a redistribution layer 161, and a redistribution via 162. The insulating layer 160 may include an insulating resin. The insulating resin may be formed of a thermosetting resin such as an epoxy resin, a thermoplastic resin such as a polyimide, or a resin in which an inorganic filler or the like is impregnated into the resin, such as a prepreg, an Ajinomoto build-up film (ABF), FR-4, or bismaleimide-triazine (BT). In an embodiment, the insulating layer 160 may be formed of a photosensitive resin such as a photo-imageable dielectric (PID). The insulating layer 160 may include a plurality of insulating layers stacked in the vertical direction (Z direction). Depending on a process, boundaries between the plurality of insulating layers may be unclear.

The redistribution layer 161 may be disposed on and within the insulating layer 160, and may redistribute connection pads 210 of a chip structure 200. The redistribution layer 161 may be formed of a metal, for example, copper (Cu), aluminum (Al), silver (Ag), tin (Sn), gold (Au), nickel (Ni), lead (Pb), titanium (Ti), or an alloy thereof. The redistribution layer 161 may perform various functions depending on a design. For example, the redistribution layer 161 may include a ground pattern, a power pattern, and a signal pattern. In this case, the signal pattern may be defined as a transmission path of various signals, such as data signals, excluding the ground pattern, the power pattern, and the like. The redistribution layer 161 may include more or fewer number of redistribution layers than those illustrated in the drawing.

The redistribution via 162 may extend in the insulating layer 160, and may be electrically connected to the redistribution layer 161. For example, the redistribution via 162 may interconnect redistribution layers 161 on different levels. The redistribution via 162 may be formed of a metal material, such as copper (Cu), aluminum (Al), silver (Ag), tin (Sn), gold (Au), nickel (Ni), lead (Pb), titanium (Ti), or an alloy thereof. The redistribution via 162 may be a filled via in which a metal material is filled in a via hole, or a conformal via in which a metal material extends along an inner wall of a via hole.

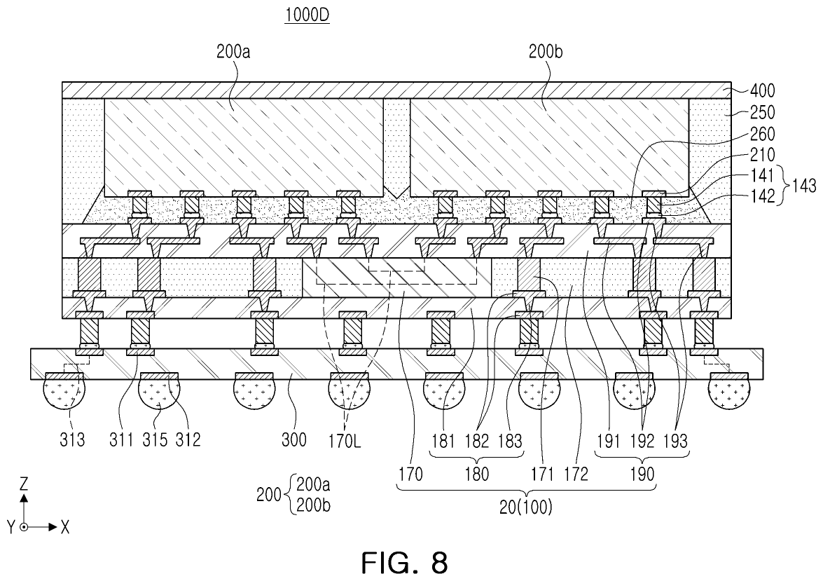

FIG. 8 is a cross-sectional view of a semiconductor package 1000D according to an embodiment.

Referring to FIG. 8, a semiconductor package 1000D according to an embodiment may have the same or similar features as those described with reference to FIGS. 1A to 7, except that a second interposer substrate 20 having a second type is included. The second interposer substrate 20 is an example of interposer substrate 100 described elsewhere herein (e.g., with reference to FIG. 1A to 6 and 9). The second interposer substrate 20 may include an interconnection chip 170 configured to electrically connect chip structures 200. For example, the second interposer substrate 20 may include a lower redistribution structure 180, an interconnection chip 170, through-vias 171, a mold 172, and an upper redistribution structure 190.

The lower redistribution structure 180 may include a dielectric layer 181, redistribution patterns 182, and redistribution vias 183. The dielectric layer 181 may be formed using a photosensitive resin. For example, the dielectric layer 181 may be formed from a polyimide (PI)-based photosensitive polymer, a polybenzoxazole (PBO)-based photosensitive polymer, a polyhydroxystyrene (PHS)-based photosensitive polymer, a novolak-based photosensitive polymer, a benzocyclobutene (BCB)-based photosensitive polymer, or a photo imageable dielectric (PID).

The redistribution patterns 182 may be disposed on or in the dielectric layer 181, and may be electrically connected to the interconnection chip 170, the through-vias 171, and a chip structure 200. The redistribution patterns 182 may be formed of, for example, copper (Cu), aluminum (Al), silver (Ag), tin (Sn), gold (Au), nickel (Ni), lead (Pb), titanium (Ti), or an alloy thereof. The redistribution patterns 182 may include a ground pattern, a power pattern, and a signal pattern according to a design. The signal pattern may provide a transmission path for various signals, such as data signals, excluding the ground pattern, the power pattern, and the like. The redistribution patterns 182 may include various types of conductive lines extending in the horizontal direction (X and/or Y).

The redistribution vias 183 may penetrate the dielectric layer 181, and may be electrically connected to the redistribution patterns 182. The redistribution vias 183 may have a shape with a side surface tapered toward a package substrate 300, for example, with side surfaces converging toward one another in a direction toward the package substrate 300. The redistribution vias 183 may be formed of, for example, copper (Cu), aluminum (Al), silver (Ag), tin (Sn), gold (Au), nickel (Ni), lead (Pb), titanium (Ti), or alloys thereof. The redistribution vias 183 may be a filled via in which a metal material is filled in a via hole, or a conformal via in which a metal material extends along an inner wall of a via hole.

The interconnection chip 170 may be disposed on the lower redistribution structure 180, for example, by being on an upper surface of the dielectric layer 181. The interconnection chip 170 may include an interconnection circuit 170L for electrically connecting the first chip structure 200a and the second chip structure 200b. The interconnection chip 170 may be a semiconductor chip in which the interconnection circuit 170L is formed on a semiconductor substrate, but is not limited thereto.

The through-vias 171 may be disposed around the interconnection chip 170, and may be electrically connected to the redistribution patterns 182. The through-vias 171 may have a post shape extending in the vertical direction (Z), corresponding to a height of the interconnection chip 170. One surface (e.g., upper surface) of the through-vias 171 may be coplanar with one surface (e.g., upper surface) of the mold 172 by a planarization process. The through-vias 171 may be formed from copper (Cu), aluminum (Al), silver (Ag), tin (Sn), gold (Au), nickel (Ni), lead (Pb), titanium (Ti), or an alloy thereof.

The mold 172 may be disposed between the lower redistribution structure 180 and the upper redistribution structure 190. The mold 172 may be formed to encapsulate the interconnection chip 170 and the through-vias 171. The mold 172 may include, for example, a thermosetting resin such as an epoxy resin, a thermoplastic resin such as a polyimide, or a prepreg, an ABF, FR-4, BT, an EMC, or the like in which these resins are impregnated with inorganic fillers.

The upper redistribution structure 190 may include an upper dielectric layer 191, upper redistribution patterns 192, and upper redistribution vias 193. The upper dielectric layer 191, the upper redistribution patterns 192, and the upper redistribution vias 193 may have substantially similar characteristics to the dielectric layer 181, the redistribution patterns 182, and the redistribution vias 183, described above, and therefore, a duplicate description thereof will be omitted. The upper redistribution patterns 192 may be connected to the interconnection circuit 170L through the upper redistribution vias 193. The chip structures 200 may be electrically connected to the interconnection chip 170 through the upper redistribution patterns 192.

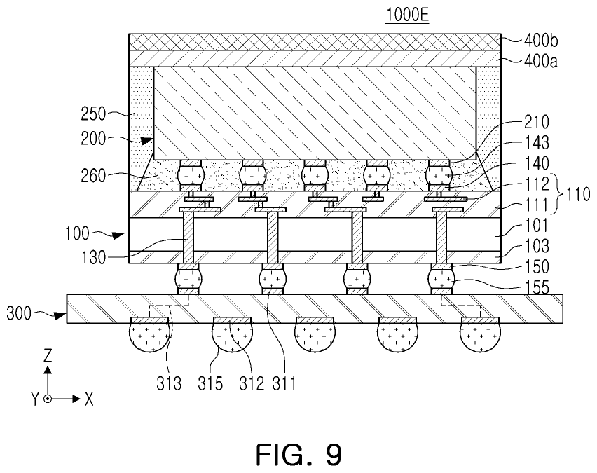

FIG. 9 is a cross-sectional view of a semiconductor package 1000E according to an embodiment.

Referring to FIG. 9, a semiconductor package 1000E according to an embodiment may have the same or similar features as those described with reference to FIGS. 1A to 8. In FIG. 9, reinforcing member 400 is formed as a plurality of layers and is an example of a reinforcing member 400 that may be implemented with the other embodiments described herein. It should be appreciated that while one chip structure 200 is shown, the embodiment of FIG. 9 may comprise one or a plurality of chip structures 200, such as described elsewhere herein.

The reinforcing member 400 may comprise a plurality of reinforcing component members 400a and 400b. For example, the plurality of reinforcing component members 400a and 400b may include a first reinforcing component member 400a and a second reinforcing component member 400b. A height of the plurality of reinforcing component members 400 a and 400 b may range from 0.5 μm to about 5 μm, with this height comprising a sum of the height of the first reinforcing component member 400a and the height of the second reinforcing component member 400b.

The plurality of reinforcing component members 400a and 400b may be formed from a metal having a coefficient of thermal expansion that is higher than a coefficient of thermal expansion of the first region including the chip structure 200 and the molding member 250. Likewise, the coefficient of thermal expansion of the plurality of reinforcing component members 400a and 400b is higher than a coefficient of thermal expansion of the second region including the interposer substrate 100, the first bumps 143, and the underfill region 260. The plurality of reinforcing component members 400a and 400b may be formed of, for example, any one of nickel (Ni), copper (Cu), or aluminum (Al). The coefficient of thermal expansion of the plurality of reinforcing component members 400 a and 400 b may be about 15×10⁻⁶K⁻¹ to 20×10⁻⁶K⁻¹.

According to an embodiment, a reinforcing member may be introduced to an upper portion of a chip structure and an upper portion of a molding member, to provide a semiconductor package having improved warpage.

While example embodiments have been illustrated and described above, it will be apparent to those skilled in the art that modifications and variations could be made without departing from the scope of the present inventive concept as defined by the appended claims.

What is claimed is:

1. A semiconductor package comprising:
a package substrate including first upper pads and first lower pads, located opposite to each other;
an interposer substrate on the package substrate, the interposer substrate including second upper pads and second lower pads, located opposite to each other, and through-electrodes electrically connecting at least a portion of the second upper pads and at least a portion of the second lower pads;
a chip structure on the interposer substrate, the chip structure including a connection pad on a lower surface of the chip structure;
first bumps disposed between the interposer substrate and the chip structure, the first bumps electrically connecting the connection pad and the second upper pads;
second bumps disposed between the interposer substrate and the package substrate, the second bumps electrically connecting the second lower pads and the first upper pads;
connection bumps below the first lower pad of the package substrate;
an underfill region disposed between the interposer substrate and the chip structure, the underfill region surrounding, with respect to a top-down view, each of the first bumps and including a side surface extending from a side surface of the chip structure to the interposer substrate;
a molding member on the interposer substrate, the molding member surrounding, with respect to a top-down view, the chip structure and the underfill region; and
a reinforcing member on the chip structure and the molding member,
wherein a coefficient of thermal expansion of a first region including the chip structure and the molding member is lower than a coefficient of thermal expansion of the reinforcing member, and
a coefficient of thermal expansion of a second region including the underfill region, the first bumps, and the interposer substrate is higher than the coefficient of thermal expansion of the first region.

2. The semiconductor package of claim 1, wherein, with respect to a top-down view, an area of each of the second lower pads is equal to or greater than an area of each of the second upper pads.

3. The semiconductor package of claim 1, wherein a ratio of a height of the underfill region relative to a height of the first region in a vertical direction is 0.05 or more.

4. The semiconductor package of claim 1, wherein the reinforcing member has a height in a vertical direction of 0.5 μm to 5 μm.

5. The semiconductor package of claim 1, wherein a height of the first region in a vertical direction is 500 μm to 700 μm.

6. The semiconductor package of claim 1, wherein a height of the second region in a vertical direction is 90 μm to 210 μm.

7. The semiconductor package of claim 1, wherein the reinforcing member is formed of at least one of nickel (Ni), copper (Cu), or aluminum (Al).

8. The semiconductor package of claim 1, wherein a gap between the first bumps is 100 μm to 150 μm.

9. The semiconductor package of claim 1, wherein an upper surface of the molding member is co-planar with an upper surface of the chip structure, and
the reinforcing member contacts the upper surface of the molding member and the upper surface of the chip structure.

10. The semiconductor package of claim 1, wherein, with respect to a top-down view, a cross-sectional dimension of one of the first bumps is 60 μm to 80 μm.

11. The semiconductor package of claim 1, wherein the coefficient of thermal expansion of the reinforcing member is 15×10⁻⁶K⁻¹ to 20×10⁻⁶K⁻¹,
the coefficient of thermal expansion of the first region is 5×10⁻⁶K⁻¹ to 10×10⁻⁶K⁻¹, and
the coefficient of thermal expansion of the second region is 10×10⁻⁶K⁻¹ to 15×10⁻⁶K⁻¹.

12. A semiconductor package comprising:
a package substrate;
an interposer substrate on the package substrate, the interposer substrate including upper pads and lower pads, located opposite to each other, through-electrodes electrically connecting at least a portion of the upper pads and at least a portion of the lower pads and a redistribution circuit connecting the upper pads and the through-electrodes;
a chip structure on the interposer substrate, the chip structure including an upper surface, a lower surface, and a chip pad on the lower surface of the chip structure;
first bumps disposed between, and electrically connecting, the interposer substrate and the chip structure;
second bumps disposed between, and electrically connecting, the interposer substrate and the package substrate;
an underfill region disposed between the interposer substrate and the chip structure, the underfill region surrounding, with respect to a top-down view, each of the first bumps;
a molding member on the interposer substrate, the molding member surrounding, with respect to a top-down view, the chip structure to expose the upper surface of the chip structure; and
a reinforcing member disposed on, and in contact with, the upper surface of the chip structure and an upper surface of the molding member,
wherein a coefficient of thermal expansion of the reinforcing member is higher than a coefficient of thermal expansion of a region including the underfill region, the first bumps, and the interposer substrate.

13. The semiconductor package of claim 12, wherein a side surface of the reinforcing member, a side surface of the molding member, and a side surface of the interposer substrate are coplanar.

14. The semiconductor package of claim 12, wherein a gap between the chip structure and the interposer substrate is 40 μm to 60 μm.

15. The semiconductor package of claim 12, wherein the reinforcing member includes at least one of nickel (Ni), copper (Cu), or aluminum (Al).

16. The semiconductor package of claim 12, wherein the coefficient of thermal expansion of the reinforcing member is 15×10⁻⁶K⁻¹ to 20×10⁻⁶K⁻¹.

17. A semiconductor package comprising:
a package substrate;
an interposer substrate on the package substrate, the interposer substrate including upper pads and lower pads, located opposite to each other, through-electrodes electrically connecting at least a portion of the upper pads and at least a portion of the lower pads, and a redistribution circuit connecting the upper pads and the through-electrodes;
a chip structure on the interposer substrate;
first bumps disposed between, and electrically connecting, the interposer substrate and the chip structure, the first bumps comprising a height between 40 μm to 60 μm;
second bumps disposed between, and electrically connecting, the interposer substrate and the package substrate;
an underfill region disposed between the interposer substrate and the chip structure, the underfill region surrounding, with respect to a top-down view, each of the first bumps;
a molding member on the interposer substrate, the molding member surrounding, with respect to a top-down view, the chip structure to expose at least a portion of an upper surface of the chip structure; and
a reinforcing member on the chip structure and the molding member,
wherein a coefficient of thermal expansion of the reinforcing member is 15×10⁻⁶K⁻¹ to 20×10⁻⁶K⁻¹,
a coefficient of thermal expansion of a first region including the chip structure and the molding member is 5×10⁻⁶K⁻¹ to 10×10⁻⁶ K⁻¹,
a coefficient of thermal expansion of a second region including the underfill region, the first bumps, and the interposer substrate is 10×10⁻⁶K⁻¹ to 15×10⁻⁶K⁻¹.

18. The semiconductor package of claim 17, wherein the reinforcing member has a height in a vertical direction of 0.5 μm to 5 μm.

19. The semiconductor package of claim 1, wherein the chip structure is a single semiconductor chip.

20. The semiconductor package of claim 1, wherein the chip structure is a stack of semiconductor chips having an upper surface including a surface of the uppermost one of the stack of semiconductor chips and having a lower surface including a surface of the lowermost one of the stack of semiconductor chips.
